(19) United States
(12) Patent Application Publication
(10) Pub. No.: US 2026/0305434 A1
(43) Pub. Date: Oct. 1, 2026

(54) METHOD FOR MANUFACTURING SEMICONDUCTOR DEVICE, AND INSULATING RESIN MATERIAL

(71) Applicant: Resonac Corporation, Minato-ku, Tokyo (JP)

(72) Inventors: Keiko UENO, Tokyo (JP); Sadaaki KATO, Tokyo (JP); Dongchul KANG, Tokyo (JP)

(21) Appl. No.: 19/477,785

(22) PCT Filed: Sep. 4, 2024
(86) PCT No.: PCT/JP2024/031716

§ 371 Date: Oct. 23, 2025

(30) Foreign Application Priority Data
Sep. 5, 2023 (WO) PCT/JP2023/032363

(51) Int. Cl. H10W 72/00; H10P 95/00; H10W 74/01

(52) U.S. Cl. CPC H10W 72/01251; H10P 95/04; H10P 95/08; H10W 72/07236; H10W 74/012

(57) ABSTRACT

A semiconductor member 10 having minute copper pillars 12 and solder bumps 13, which are micro-bumps, is prepared. An underfill material is applied and spread on the semiconductor member 10 so as to cover the copper pillars 12 and the solder bumps 13, and is cured. This forms an insulating resin layer 20 that is thicker than the height of connection portions 14. The thick insulating resin layer 20 is ground by a CMP equipment to expose surfaces 13a of the solder bumps 13A from the insulating resin layer. According to this method, the height uniformity and the surface smoothness of the bumps 13 can be improved. Voids are also less likely to occur due to the improved surface smoothness. Since the insulating resin layer 20 covers each bump 13, bridges are also less likely to occur. This method may be applied to CoW and WoW.

### TECHNICAL FIELD

The present disclosure relates to a method for manufacturing a semiconductor device, and an insulating resin material.

### BACKGROUND ART

Flip-chip bonding is known in which conductive protrusions called bumps are formed on a semiconductor chip to directly connect the semiconductor chip and a wiring circuit board. Attempts have been made to stack semiconductor chips in multiple stages, such as 4, 8, and 12 stages, using such flip-chip bonding, and along with this, there is a tendency for the height of the bumps to become lower and the bump diameter to become smaller (see, for example, Non Patent Literature 1 and Non Patent Literature 2).

### CITATION LIST

### Non Patent Literature

Non Patent Literature 1: Julia Woertink et al., “From C4 to micro-bump: Adapting lead free solder electroplating processes to next-gen advanced packaging applications”, 2014 Electronic Components and Technology Conference, pp. 342-347, 2014.
Non Patent Literature 2: Mi-Seok Park et. al, “Effects of the degradation of methane sulfonic acid electrolyte on the collapse failure of Sn—Ag alloy solders for flip-chip interconnections”, The Royal Society of Chemistry 2017, pp. 23136-23142, 2017.

### SUMMARY OF INVENTION

### Technical Problem

With such micro-bumps, because the bumps are minute, it may be difficult to make the heights of a plurality of bumps uniform and to make the surface of each bump smooth. Also, since the bump pitch becomes smaller with micro-bumps, bridges are more likely to occur between bumps. Such problems with micro-bumps affect the manufacturing yield of semiconductor devices.

An object of the present disclosure is to provide a method for manufacturing a semiconductor device and an insulating resin material that can improve the manufacturing yield of semiconductor devices.

### Solution to Problem

[1] The present disclosure provides a method for manufacturing a semiconductor device as one aspect. This method for manufacturing a semiconductor device includes: preparing a joined body including a semiconductor substrate, a connection portion provided on a main surface of the semiconductor substrate, and an insulating resin layer provided on the main surface of the semiconductor substrate so as to cover the connection portion; and grinding the insulating resin layer of the joined body. In the grinding, the insulating resin layer is ground such that a surface of the connection portion is exposed.

In this method for manufacturing a semiconductor device, after the connection portion is covered with the insulating resin layer, the insulating resin layer is ground such that the surface of the connection portion is exposed. In this case, improvement in the height uniformity and surface smoothness of the connection portion can be reliably achieved by grinding. Voids are also less likely to occur due to the improved surface smoothness. Also, since the insulating resin layer covers the connection portion, bridges are also less likely to occur. Therefore, according to this method for manufacturing a semiconductor device, the manufacturing yield of semiconductor devices can be improved even when the connection portions are miniaturized.

[2] In the method for manufacturing a semiconductor device of [1] above, it is preferable that a part of the connection portion is ground together with the insulating resin layer in the grinding. In this case, since a part of the connection portion is ground, improvement in the height uniformity and surface smoothness of the connection portion can be reliably achieved by grinding.

[3] In the method for manufacturing a semiconductor device of [1] or [2] above, the connection portion may include a connection terminal provided on the main surface of the semiconductor substrate, and a bump provided on the connection terminal. In the grinding, it is preferable that a part of the bump is ground such that a surface of the bump is exposed from the insulating resin layer. In this case, since a part of the bump constituting the connection portion is ground, improvement in the height uniformity and surface smoothness of the bump can be reliably achieved by grinding.

[4] In the method for manufacturing a semiconductor device of any one of [1] to [3] above, the preparing the joined body may include preparing a semiconductor member having the semiconductor substrate and the connection portion, and forming the insulating resin layer by providing a liquid insulating resin material on the main surface of the semiconductor substrate so as to cover the connection portion of the semiconductor member. The insulating resin layer is thicker than the height of the connection portion when provided on the semiconductor substrate. In this case, since a liquid insulating resin material is used, the insulating resin material can easily reach the details even when the connection portion is miniaturized. This makes it possible to reliably ensure the bridge prevention function of the insulating resin layer.

[5] In the method for manufacturing a semiconductor device of any one of [1] to [3] above, the preparing the joined body may include preparing a semiconductor member having the semiconductor substrate and the connection portion, and forming the insulating resin layer by attaching a film-like insulating resin material to the main surface of the semiconductor substrate so as to cover the connection portion of the semiconductor member. The insulating resin layer is thicker than the height of the connection portion when attached to the semiconductor substrate. In this case, since a film-like insulating resin layer is used, variations in the height of the insulating resin layer to be formed can be suppressed, and the subsequent grinding process can be performed more appropriately.

[6] In the method for manufacturing a semiconductor device of [4] or [5] above, the preparing the joined body may further include performing a curing process on the insulating resin layer of the joined body before the grinding. When a liquid insulating resin material is used, this curing process can semi-cure the material, making it possible to reliably perform the grinding process of the insulating resin layer. Also, even when a film-like insulating resin material is used, the material may have viscosity and be soft, and in that case, by performing the curing process, it becomes possible to reliably perform the grinding process of the insulating resin layer. Note that the curing process here is sufficient if the material is cured to an extent that allows for cutting, and it does not need to be completely cured.

[7] In the method for manufacturing a semiconductor device of any one of [1] to [6] above, it is preferable that the insulating resin layer is ground using at least one of a grinder, a surface planer, and a CMP equipment in the grinding. In this case, it becomes possible to grind the insulating resin layer more reliably.

[8] In the method for manufacturing a semiconductor device of any one of [1] to [7] above, the insulating resin layer may contain an epoxy resin, a curing agent, and an inorganic filler.

[9] In the method for manufacturing a semiconductor device of any one of [1] to [7] above, the insulating resin layer may contain an epoxy resin, a curing agent, and a fluxing agent.

[10] The method for manufacturing a semiconductor device of any one of [1] to [9] above may further include singulating the joined body into a plurality of semiconductor chips after grinding the insulating resin layer, and mounting at least one semiconductor chip of the plurality of semiconductor chips on a substrate.

[11] In the method for manufacturing a semiconductor device of [10] above, the substrate may be provided with a terminal to be connected to the connection portion of the joined body, and the terminal may be subjected to a surface treatment for connecting to the solder of the connection portion. In the manufacturing method of the present disclosure, grinding is performed such that the surface of the connection portion of the joined body is exposed, but by subjecting the terminal of the receiving substrate to a predetermined surface treatment, the connection between the connection portion (bump, for example, solder bump) and the terminal can be made more reliable. Note that examples of such a surface treatment can include, but are not limited to, NiAu treatment, Organic Solderability Preservatives (OSP), and the like.

[12] In the method for manufacturing a semiconductor device of [10] or [11] above, the substrate may be a semiconductor wafer having another connection portion, and in the mounting, the connection portion of the at least one semiconductor chip may be connected to the another connection portion of the semiconductor wafer. In this case, the method for manufacturing a semiconductor device according to the present disclosure can be applied to so-called Chip on Wafer (CoW) to achieve thinning and miniaturization of the semiconductor device.

[13] The method for manufacturing a semiconductor device of any one of [1] to [9] above may further include bonding a first semiconductor wafer, which is the joined body after grinding the insulating resin layer, to a second semiconductor wafer having another connection portion. In the bonding, the connection portion of the first semiconductor wafer may be connected to the another connection portion of the second semiconductor wafer. In this case, the method for manufacturing a semiconductor device according to the present disclosure can be applied to so-called Wafer on Wafer (WoW) to achieve thinning and miniaturization of the semiconductor device.

[14] The present disclosure provides an insulating resin material as another aspect. This insulating resin material is used for forming the insulating resin layer in a method for manufacturing a semiconductor device, the method including: preparing a joined body having a semiconductor substrate, a connection portion provided on a main surface of the semiconductor substrate, and an insulating resin layer provided on the main surface of the semiconductor substrate so as to cover the connection portion; and grinding the insulating resin layer of the joined body such that a surface of the connection portion is exposed.

### Advantageous Effects of Invention

According to the present disclosure, the manufacturing yield of semiconductor devices can be improved.

### BRIEF DESCRIPTION OF DRAWINGS

FIG. 1 is a schematic cross-sectional view showing an example of a method for manufacturing a semiconductor device.

FIG. 2 is a schematic cross-sectional view showing an example of the method for manufacturing a semiconductor device.

FIG. 3 is a schematic cross-sectional view showing an example of the method for manufacturing a semiconductor device.

FIG. 4(a) to (d) of FIG. 4 are cross-sectional views showing a case where the method for manufacturing a semiconductor device according to the present embodiment is applied to CoW (first modification).

FIG. 5(a) to (c) of FIG. 5 are cross-sectional views showing a case where the method for manufacturing a semiconductor device according to the present embodiment is applied to WoW (second modification).

### DESCRIPTION OF EMBODIMENTS

Hereinafter, embodiments according to the present invention will be described in detail with reference to the drawings. In the following description, the same or corresponding parts are denoted by the same reference signs, and redundant description will be omitted. Also, positional relationships such as up, down, left, and right are based on the positional relationships shown in the drawings unless otherwise specified. Furthermore, the dimensional ratios in the drawings are not limited to the illustrated ratios.

In this specification, the term “layer” includes not only a structure with a shape formed over the entire surface when observed as a plan view, but also a structure with a shape formed in a part. In this specification, the term “step” is included in this term not only as an independent step, but also if the intended action of the step is achieved even when it cannot be clearly distinguished from other steps.

A numerical range indicated using “to” in this specification indicates a range including the numerical values described before and after “to” as the minimum value and the maximum value, respectively. In a numerical range described stepwise in this specification, the upper limit value or the lower limit value of a numerical range of one stage may be replaced with the upper limit value or the lower limit value of a numerical range of another stage. In a numerical range described in this specification, the upper limit value or the lower limit value of the numerical range may be replaced with a value shown in an example.

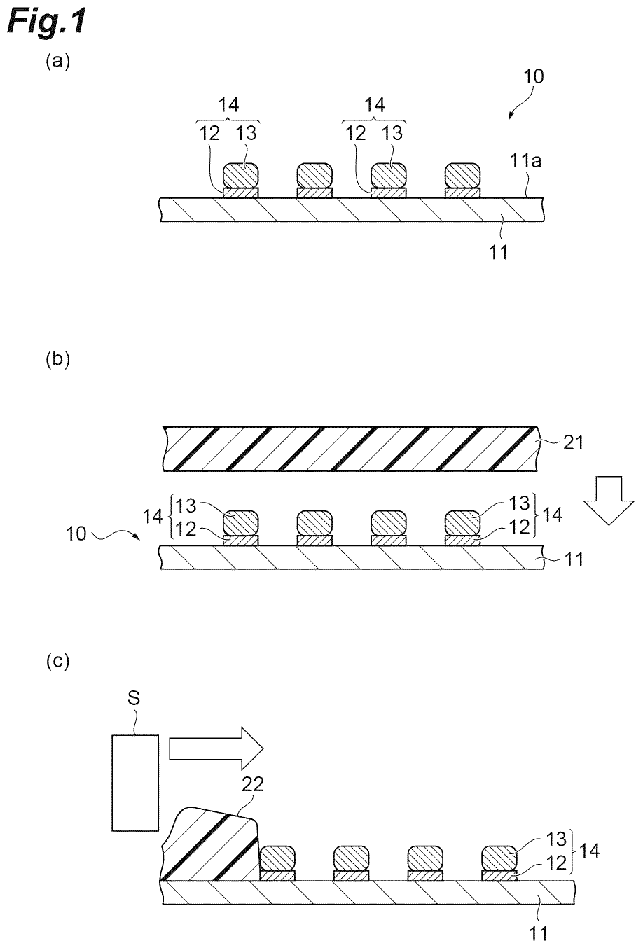

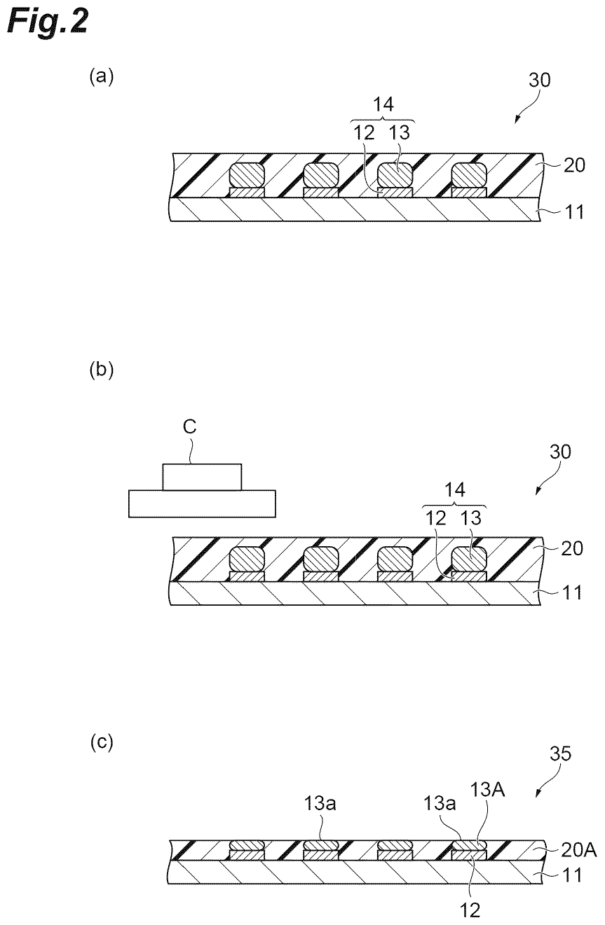

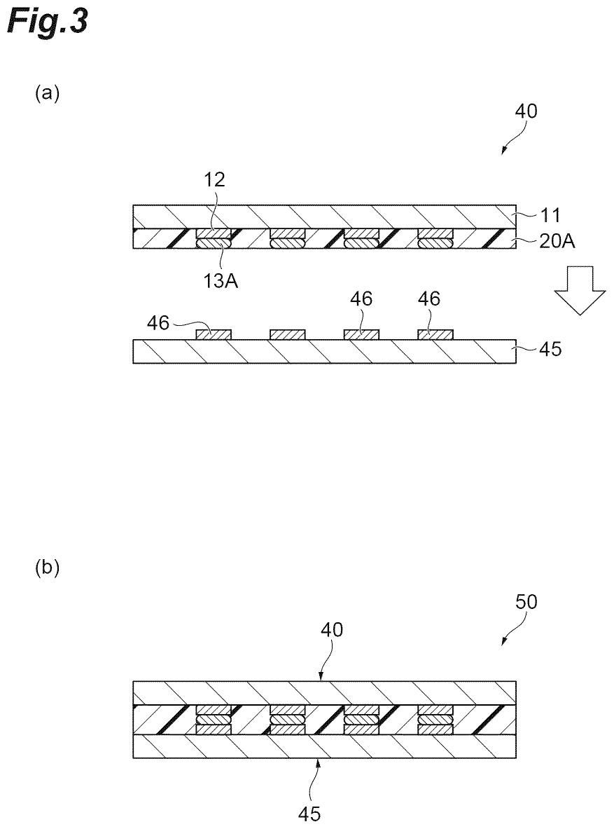

A method for manufacturing a semiconductor device according to the present embodiment will be described with reference to FIG. 1 to FIG. 3. FIG. 1, FIG. 2, and FIG. 3 are schematic cross-sectional views sequentially showing the method for manufacturing a semiconductor device.

As shown in (a) of FIG. 1, a semiconductor member 10 is prepared, which has a semiconductor substrate 11, and a plurality of connection terminals 12 and a plurality of bumps 13 provided on a main surface 11a of the semiconductor substrate 11. The semiconductor substrate 11 is, for example, a semiconductor substrate including an elemental semiconductor composed of the same kind of element such as silicon or germanium, or a compound semiconductor such as gallium arsenide or indium phosphide. In the present embodiment, a case where the semiconductor substrate 11 is a semiconductor wafer will be described as an example, but the semiconductor substrate 11 may be a semiconductor chip. The thickness of the semiconductor substrate 11 is, for example, 10 μm to 800 μm.

Each of the bumps 13 is provided on a corresponding connection terminal 12. The connection terminal 12 and the bump 13 can be a metal layer containing one or more metals selected from gold, silver, copper, solder, nickel, tin, and lead. The main component of the solder may be, for example, tin-silver, tin-lead, tin-bismuth, tin-copper, or tin-silver-copper. The metal constituting the connection terminal 12 and the bump 13 may be gold, silver, copper, or solder, may be silver, copper, or solder, may be copper or solder, or may be solder. The connection terminal 12 and the bump 13 may be a metal layer formed by plating. The connection terminal 12 and the bump 13 may be a single layer or may include a plurality of metal layers. As an example, the connection terminal 12 may be a copper pillar, and the bump 13 may be a solder bump.

The diameter of each of the connection terminal 12 and the bump 13 may be, for example, 20 μm or less, or may be 10 μm or less. The total height of the connection portion 14 including both the connection terminal 12 and the bump 13 may be, for example, 20 μm or less, may be 15 μm or less, or may be 10 μm or less. The pitch (meaning the center pitch) between adjacent connection portions 14 may be, for example, 20 μm or less, or may be 15 μm or less. Such a connection portion 14 may be a so-called micro-bump.

Subsequently, when the semiconductor member 10 is prepared, a liquid insulating resin material is prepared. The liquid insulating resin material contains, for example, an epoxy resin, a curing agent, and a inorganic filler. The liquid insulating resin material may be an underfill material, and a detailed configuration example will be described later. Then, the liquid insulating resin material is applied to the semiconductor substrate 11 so as to cover the plurality of connection terminals 12 and the plurality of bumps 13 of the semiconductor member 10, to form an insulating resin layer 20 as shown in (a) of FIG. 2. When a liquid insulating resin material is used, the insulating resin material may be applied, spread on the semiconductor substrate 11 by spin coating or the like so as to cover the connection terminals 12 and the bumps 13, and then cured. In this case, the curing process may be, for example, to an extent that semi-cures the liquid insulating resin material. The curing here may be thermosetting or photocuring (ultraviolet curing). As described above, a joined body 30 is formed in which the insulating resin layer 20 is provided on the main surface 11a of the semiconductor substrate 11 so as to cover the connection portions 14. The joined body 30 includes the semiconductor substrate 11, the plurality of connection portions 14, and the insulating resin layer 20.

The insulating resin layer 20 is configured to be thicker than the height of the connection portion 14 at least after being provided (applied and spread) on the semiconductor substrate 11 (after curing, if cured). The insulating resin layer 20 may have a thickness of 1.2 times or more, 1.5 times or more, or 2 times or more the height of the connection portion 14 after being provided on the semiconductor substrate 11. Also, the insulating resin layer 20 may have a thickness of 30 μm or more, or 20 μm or more, after being provided on the semiconductor substrate 11.

The formation of the insulating resin layer 20 is not limited to the above method. For example, as shown in (b) of FIG. 1, when the semiconductor member 10 is prepared, a film adhesive 21 is prepared. The film adhesive 21 is an insulating adhesive such as a non-conductive film (NCF), and contains, for example, an epoxy resin, a curing agent, and a fluxing agent. Then, the film adhesive 21 is attached to the semiconductor substrate 11 so as to cover the plurality of connection terminals 12 and the plurality of bumps 13 of the semiconductor member 10, to become the insulating resin layer 20 shown in (a) of FIG. 2. In this attachment, for example, the film adhesive 21 is laminated to the semiconductor member 10 by applying pressure for 30 seconds to 10 minutes while heating the semiconductor member 10 and the film adhesive 21 to 60 to 100° C. The film adhesive 21 can be attached to the main surface 11a of the semiconductor substrate 11 by, for example, a hot press, roll lamination, or vacuum lamination. Note that after attaching the film adhesive 21 to the semiconductor substrate 11 and before grinding, a curing process may be performed on the film adhesive 21 to form the insulating resin layer 20. The curing at this time does not completely cure the film adhesive 21, but lightly cures it, and it is sufficient if it is cured to an extent that allows for grinding.

Also, for forming the insulating resin layer 20, as shown in (c) of FIG. 1, a paste-like insulating resin material 22 is prepared, this insulating resin material 22 is applied onto the main surface 11 a of the semiconductor substrate 11, and may be printed by a squeegee S or the like. The insulating resin layer 20 may be formed thereby. In this case as well, the insulating resin layer 20 is configured to be thicker than the height of the connection portion 14 after being provided (applied and spread) on the semiconductor substrate 11 (after curing, if cured), as shown in (a) of FIG. 2.

Subsequently, as shown in (b) and (c) of FIG. 2, the insulating resin layer 20 of the joined body 30 including the semiconductor substrate 11, the plurality of connection portions 14, and the insulating resin layer 20, is ground. As an apparatus C for grinding the insulating resin layer 20, the insulating resin layer 20 is ground to a predetermined thickness using at least one of a grinder, a surface planer, and a chemical mechanical polishing (CMP) equipment. As a method for grinding the insulating resin layer 20, it is preferable to use a CMP equipment. This makes the ground surface smooth. In the step of grinding the insulating resin layer, the insulating resin layer 20 is ground such that a surfaces 13a of the bumps 13A are exposed from the insulating resin layer 20A. During this grinding, a part of the bump 13 of the connection portion 14 may be ground together with the insulating resin layer 20. This allows the surface 13a of the bump 13A to be more reliably exposed from the insulating resin layer.

Subsequently, when the insulating resin layer 20A is ground and thinned and the surfaces 13a of the bumps 13A are exposed as shown in (c) of FIG. 2, the joined body 35 (semiconductor wafer) after grinding the insulating resin layer 20A is singulated into a plurality of semiconductor chips (not shown). This makes it possible to easily obtain semiconductor chips provided with minute bumps (micro-bumps, etc.).

Subsequently, as shown in (a) and (b) of FIG. 3, at least one semiconductor chip 40 of the plurality of semiconductor chips is placed on a wiring board 45 (substrate), and heated and pressurized to mount the semiconductor chip 40 on the wiring board 45. As a result, a semiconductor device 50 is manufactured in which each bump 13A of the semiconductor chip 40 is connected to a connection terminal 46 (terminal) of the wiring board 45, and the semiconductor substrate 11 and the wiring board 45 are fixed to each other by the insulating resin layer 20A. The connection terminal 46 of the wiring board 45 may be subjected to a surface treatment such as NiAu treatment or OSP treatment before mounting, so that the connection with the bump 13A can be reliably made. In the OSP treatment, a water-soluble preflux can be applied to perform rust prevention treatment. Note that when the semiconductor chip 40 has a through-silicon via (TSV) structure, a multi-stage semiconductor device may be formed by three-dimensionally stacking a plurality of semiconductor chips 40 and then collectively heating and pressurizing the stacked plurality of semiconductor chips 40.

As described above, in the method for manufacturing a semiconductor device according to the present embodiment, after the connection portion 14 is covered with the insulating resin layer 20, the insulating resin layer 20 is ground such that the surface 13a of the connection portion 14 (bump 13) is exposed. This makes it possible to easily adjust the height of the connection portion 14 and the smoothness of the surface 13a of the connection portion 14 (bump 13) by grinding. Voids are also less likely to occur due to the improved smoothness of the surface 13a. Also, since the insulating resin layer 20A covers the connection portion 14, bridges are also less likely to occur during mounting. Therefore, according to this method for manufacturing a semiconductor device, the manufacturing yield of semiconductor devices can be improved even when the connection portion 14 is miniaturized (in the case of micro-bumps).

In the method for manufacturing a semiconductor device according to the present embodiment, when grinding the insulating resin layer 20, a part of the connection portion 14 (bump 13) is ground together with the insulating resin layer 20. Since a part of the connection portion 14 (bump 13) is ground in this way, improvement in the height uniformity of the connection portion 14 and the smoothness of the surface 13a of the bump 13 can be reliably achieved by grinding.

In the method for manufacturing a semiconductor device according to the present embodiment, when preparing the joined body 30, the insulating resin layer 20 is formed by providing a liquid insulating resin material on the main surface 11a of the semiconductor substrate 11 so as to cover the connection portion 14 of the semiconductor member 10. Since a liquid insulating resin material is used in this way, the insulating resin material can easily reach the details even when the connection portion 14 is miniaturized. This makes it possible to reliably ensure the bridge prevention function of the insulating resin layers 20, 20A.

In the method for manufacturing a semiconductor device according to the present embodiment, when preparing the joined body 30, the insulating resin layer 20 may be formed by attaching the film adhesive 21 to the main surface 11a of the semiconductor substrate 11 so as to cover the connection portion 14 of the semiconductor member 10. When such a film-like insulating resin layer is used, variations in the height of the insulating resin layer 20 to be formed can be suppressed, and the subsequent grinding process can be performed more appropriately.

In the method for manufacturing a semiconductor device according to the present embodiment, when preparing the joined body 30, a curing process may be performed on the insulating resin layer 20 of the joined body 30 before grinding. When a liquid insulating resin material is used, this curing process can semi-cure it, making it possible to reliably perform the grinding process of the insulating resin layer 20. Also, even when the film adhesive 21 is used, the material may have viscosity and be soft, and in that case, by performing the curing process, it becomes possible to reliably perform the grinding process of the insulating resin layer 20. Note that the curing at this stage is sufficient if it is cured to an extent that allows for the grinding process, and it does not need to be complete curing.

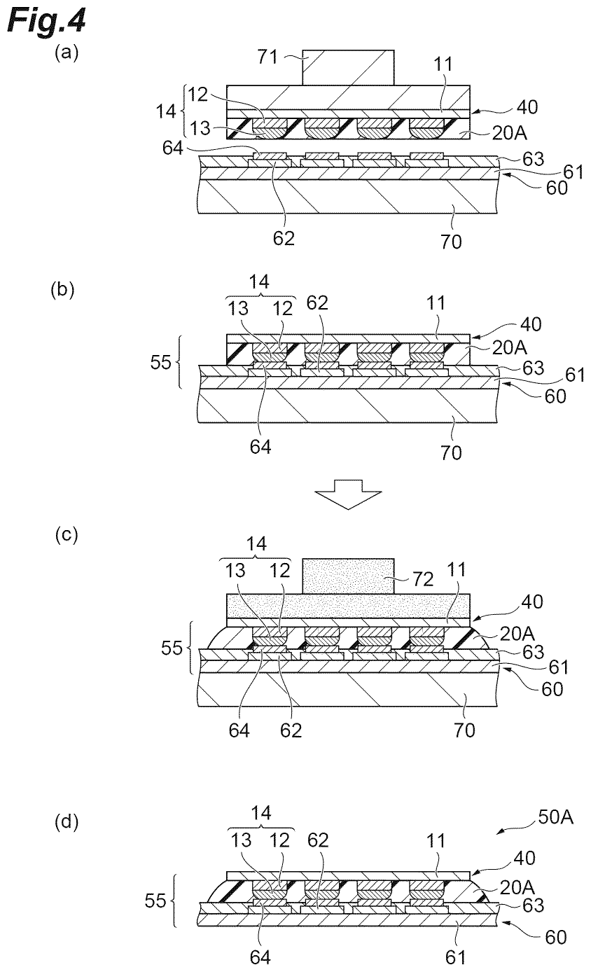

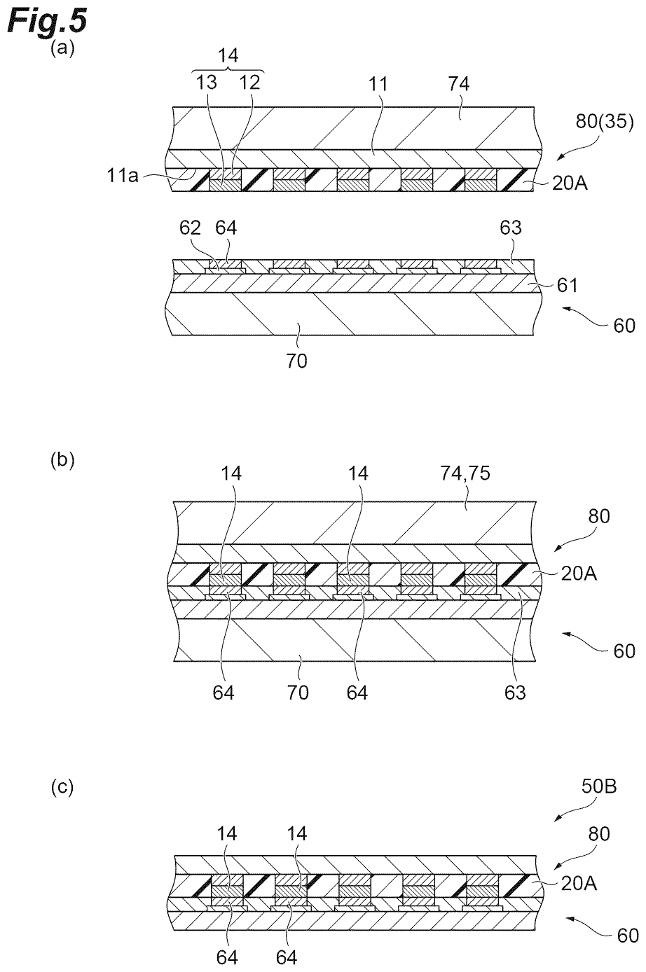

The method for manufacturing a semiconductor device according to the present embodiment is not limited to the method described above, and may be applied to Chip-on-Wafer (CoW) or Wafer-on-Wafer (WoW). (a) to (d) of FIG. 4 are cross-sectional views showing a case where the method for manufacturing a semiconductor device according to the present embodiment is applied to CoW (first modification). (a) to (c) of FIG. 5 are cross-sectional views showing a case where the method for manufacturing a semiconductor device according to the present embodiment is applied to WoW (second modification).

In the method for manufacturing a semiconductor device according to the first modification, the joined body 35 is prepared and the joined body 35 is singulated into a plurality of semiconductor chips 40 by a method similar to the method for manufacturing a semiconductor device according to the present embodiment described above (see FIG. 1, FIG. 2, and FIG. 3). That is, after covering the connection portions 14 with the thicker insulating resin layer 20, the joined body 35 obtained by grinding the insulating resin layer 20 such that the surfaces 13a of the connection portions 14 are exposed is singulated. As a result, as shown in (a) of FIG. 4, a semiconductor chip 40 is prepared. Also, a semiconductor wafer 60 (substrate) for mounting the semiconductor chip 40 is prepared. The semiconductor wafer 60 has a wafer body 61, a wiring 62 provided on the wafer body 61, a passivation film 63 provided on the wafer body 61 and covering the wiring 62, and a plurality of connection portions 64 provided on the wiring 62. The connection portion 64 is a connection terminal formed from a metal such as gold, silver, or copper, for example.

Subsequently, the semiconductor wafer 60 is placed on a heated stage 70 such that the connection portions 64 face upward. Then, the semiconductor chip 40 is thermocompression bonded to the semiconductor wafer 60 by a pressure bonding tool 71. At this time, the semiconductor chip 40 having the plurality of connection portions 14 is thermocompression bonded to the semiconductor wafer 60 having the plurality of connection portions 64 with the insulating resin layer 20A interposed therebetween. As a result, as shown in (b) of FIG. 4, a temporarily bonded body 55 is formed. The heating temperature of the stage 70 is a temperature lower than the melting point of the connection portion 14 (especially solder 13) and the melting point of the connection portion 64, and may be, for example, 60 to 150° C., or 70 to 100° C. The temperature of the pressure bonding tool 71 may be, for example, 80 to 350° C., or 100 to 170° C. The time for thermocompression bonding to form the temporarily bonded body 55 may be, for example, 5 seconds or less, 3 seconds or less, or 2 seconds or less.

Subsequently, as shown in (c) of FIG. 4, the temporarily bonded body 55 on the heated stage 70 is pressurized using a pressure bonding tool 72 while being heated to a temperature equal to or higher than at least one of the melting point of the connection portion 14 (especially solder 13) and the melting point of the connection portion 64. The temperature of the pressure bonding tool 72 may be, for example, 180° C. or higher, 220° C. or higher, or 250° C. or higher, and may be 350° C. or less, 320° C. or less, or 300° C. or less. The heating temperature of the stage 70 during thermocompression bonding by the pressure bonding tool 72 may be 60 to 150° C., or 70 to 100° C. The time for thermocompression bonding by the pressure bonding tool 72 may be, for example, 5 seconds or less, 3 seconds or less, or 2 seconds or less.

As a result, as shown in (d) of FIG. 4, the connection portion 14 of the semiconductor chip 40 is electrically connected to the connection portion 64 of the semiconductor wafer 60. The connection portions 14, 64 electrically connected to each other are encapsulated by the cured insulating resin layer 20A. As a result, a semiconductor device 50A is formed. Note that a semiconductor device 50A having a plurality of semiconductor chips 40 may be formed by sequentially mounting a plurality of semiconductor chips 40 on one semiconductor wafer 60 via the insulating resin layer 20A. Also, the joined body 35 before being singulated may be used as the semiconductor wafer 60, and the semiconductor chip 40 may be mounted on such a semiconductor wafer 60. The semiconductor device 50A may be further singulated into individual semiconductor devices.

Next, a method for manufacturing a semiconductor device according to a second modification will be described. In the method for manufacturing a semiconductor device according to the second modification, the joined body 35 is prepared by a method similar to the method for manufacturing a semiconductor device according to the present embodiment described above (see FIG. 1 and FIG. 2). That is, after covering the connection portions 14 with the thicker insulating resin layer 20, the insulating resin layer 20 is ground to obtain the joined body 35. As shown in (a) of FIG. 5, the joined body 35 is, for example, a semiconductor wafer 80 having an insulating resin layer 20A. The semiconductor wafer 80 has a semiconductor substrate 11, a plurality of connection portions 14 provided on a main surface 11a of the semiconductor substrate 11, and an insulating resin layer 20A provided on the main surface 11a of the semiconductor substrate 11 and covering the plurality of connection portions 14. Each connection portion 14 has a connection terminal 12 and a bump 13. Also, a semiconductor wafer 60 for bonding with the semiconductor wafer 80 is prepared. The semiconductor wafer 60 has a wafer body 61, a wiring 62, a passivation film 63, and connection portions 64, similarly to the first modification.

Subsequently, the semiconductor wafer 60 is placed on a heated stage 70 such that the connection portions 64 face upward. Then, the semiconductor wafer 80 is thermocompression bonded to the semiconductor wafer 60 by a pressure bonding tool 74. At this time, the semiconductor wafer 80 having the plurality of connection portions 14 is bonded to the semiconductor wafer 60 having the plurality of connection portions 64 by thermocompression bonding with the insulating resin layer 20A interposed therebetween. As a result, as shown in (b) of FIG. 5, a temporarily bonded body is formed. The heating temperature of the stage 70 is a temperature lower than the melting point of the connection portion 14 (especially solder 13) and the melting point of the connection portion 64, and may be, for example, 60 to 150° C., or 70 to 100° C. The temperature of the pressure bonding tool 74 may be, for example, 80 to 350° C., or 100 to 170° C. The time for thermocompression bonding to form the temporarily bonded body may be, for example, 5 seconds or less, 3 seconds or less, or 2 seconds or less.

Subsequently, the temporarily bonded body on the heated stage 70 is pressurized using a pressure bonding tool 75 while being heated to a temperature equal to or higher than at least one of the melting point of the connection portion 14 (especially solder 13) and the melting point of the connection portion 64. The temperature of the pressure bonding tool 75 may be, for example, 180° C. or higher, 220° C. or higher, or 250° C. or higher, and may be 350° C. or less, 320° C. or less, or 300° C. or less. The heating temperature of the stage 70 during thermocompression bonding by the pressure bonding tool 75 may be 60 to 150° C., or 70 to 100° C. The time for thermocompression bonding by the pressure bonding tool 72 may be, for example, 5 seconds or less, 3 seconds or less, or 2 seconds or less.

As a result, as shown in (c) of FIG. 5, the connection portion 14 of the semiconductor wafer 80 is electrically connected to the connection portion 64 of the semiconductor wafer 60. The connection portions 14, 64 electrically connected to each other are encapsulated by the cured insulating resin layer 20A. As a result, a semiconductor device 50B is formed. Note that such a semiconductor device 50B may be singulated into individual semiconductor devices.

Even in the method for manufacturing a semiconductor device according to such a modification, after the connection portions 14 are covered with the insulating resin layer 20, the insulating resin layer 20 is ground such that the surfaces 13a of the connection portions 14 (bumps 13) are exposed. This makes it possible to easily adjust the height of the connection portions 14 and the smoothness of the surfaces 13a of the connection portions 14 (bumps 13) by grinding. Voids are also less likely to occur due to the improved smoothness of the surfaces 13a. Also, since the insulating resin layer 20A covers the connection portions 14, bridges are also less likely to occur during mounting. Therefore, even in the methods for manufacturing a semiconductor device according to these modifications, the manufacturing yield of the semiconductor devices 50A. 50B can be similarly improved even when the connection portions 14 are miniaturized (in the case of micro-bumps). Note that the methods for manufacturing a semiconductor device according to these modifications can also similarly exhibit the other operational effects of the method for manufacturing a semiconductor device according to the embodiment described above.

### [Underfill Material]

The underfill material of the present disclosure includes an epoxy resin, a curing agent, and an inorganic filler, as described above.

The type of epoxy resin contained in the underfill material is not particularly limited. The epoxy resin may include an epoxy resin having two epoxy groups in one molecule (also referred to as a bifunctional epoxy resin), may include an epoxy resin having three epoxy groups in one molecule (also referred to as a trifunctional epoxy resin, etc.), and these may be used in combination. In the present disclosure, a monomer compound (epoxy compound) having one epoxy group is also referred to as an epoxy resin.

As long as the underfill material as a whole is liquid at room temperature (25° C., the same applies hereinafter), the epoxy resin may be solid or liquid at room temperature, or both may be used in combination. From the viewpoint of lowering the viscosity of the underfill material, it is preferable to use an epoxy resin that is liquid at room temperature.

Examples of the epoxy resin include bisphenol type epoxy resins, naphthalene type epoxy resins, glycidylamine type epoxy resins, hydrogenated bisphenol type epoxy resins, alicyclic epoxy resins, alcohol ether type epoxy resins, cycloaliphatic type epoxy resins, fluorene type epoxy resins, and siloxane-based epoxy resins. One type of epoxy resin may be used alone, or two or more types may be used in combination. Among these, from the viewpoint of fluidity, it is preferable that the epoxy resin includes a bisphenol type epoxy resin.

The type of bisphenol type epoxy resin is not particularly limited, and examples include bisphenol A type epoxy resins, bisphenol F type epoxy resins, bisphenol AD type epoxy resins, and the like. Among the above, from the viewpoint of excellent handleability as an underfill material, the bisphenol type epoxy resin is preferably one that is liquid at room temperature, and more preferably a bisphenol F type epoxy resin that is liquid at room temperature. The bisphenol type epoxy resin that is liquid at room temperature may be a synthetic product or a commercially available product.

When the epoxy resin includes a bisphenol type epoxy resin, the proportion of the bisphenol type epoxy resin in the total amount of epoxy resin is not particularly limited and can be selected according to the desired properties of the underfill material. For example, it may be 5 mass % to 90 mass %, may be 5 mass % to 75 mass %, or may be 5 mass % to 60 mass %.

The content ratio of the epoxy resin to the total amount of the underfill material is not particularly limited. The content ratio of the epoxy resin to the total amount of the underfill material is preferably 0.5 mass % to 75 mass %, more preferably 20 mass % to 70 mass %, and even more preferably 25 mass % to 70 mass %, from the viewpoints of viscosity, glass transition temperature, heat resistance, and the like.

The type of curing agent contained in the underfill material is not particularly limited and may be selected according to the desired properties of the underfill material. Examples of the type of curing agent include amine curing agents, phenol curing agents, acid anhydride curing agents, polymercaptan curing agents, polyaminoamide curing agents, isocyanate curing agents, blocked isocyanate curing agents, and the like. One type of curing agent may be used alone, or two or more types may be used in combination.

The curing agent used for the underfill material is preferably one that is liquid at room temperature, and from the viewpoints of low water absorption and adhesion to an adherend, it is preferably an amine curing agent. Examples of the amine curing agent include aliphatic amine compounds such as diethylenetriamine, triethylenetetramine, n-propylamine, 2-hydroxyethylaminopropylamine, cyclohexylamine, and 4,4′-diamino-dicyclohexylmethane; aromatic amine compounds such as diethyltoluenediamine, 3,3′-diethyl-4,4′-diaminodiphenylmethane, and 2-methylaniline; imidazole compounds such as imidazole, 2-methylimidazole, 2-ethylimidazole, and 2-isopropylimidazole; and imidazoline compounds such as imidazoline, 2-methylimidazoline, and 2-ethylimidazoline. Among these, as the amine curing agent, an aromatic amine compound is preferable.

The blending ratio of the epoxy resin and the curing agent is preferably set such that the ratio of the number of functional groups of the curing agent (active hydrogen in the case of an amine curing agent) to the number of epoxy groups of the epoxy resin (number of functional groups of curing agent/number of epoxy groups of epoxy resin) is set in the range of 0.5 to 2.0, more preferably in the range of 0.6 to 1.3, and even more preferably in the range of 0.8 to 1.2, from the viewpoint of suppressing the unreacted components of each.

The type of inorganic filler contained in the underfill material is not particularly limited. Specifically, inorganic materials such as silica, alumina, calcium carbonate, zirconium silicate, calcium silicate, silicon nitride, aluminum nitride, boron nitride, beryllia, zirconia, zircon, forsterite, steatite, spinel, mullite, titania, talc, clay, and mica can be used. Among the above inorganic fillers, silica is preferable from the viewpoint of reducing the coefficient of thermal expansion, and alumina is preferable from the viewpoint of improving thermal conductivity. One type of inorganic filler may be used alone, or two or more types may be used in combination.

The underfill material may include various additives such as a curing accelerator, a stress relaxation agent, a coupling agent, and a colorant, in addition to the components described above. The underfill material may include various additives well-known in the art as necessary, in addition to the additives exemplified below.

### REFERENCE SIGNS LIST

10 . . . semiconductor member, 11 . . . semiconductor substrate, 11a . . . main surface, 12 . . . connection terminal, 13, 13A . . . bump, 13a . . . surface, 14, 64 . . . connection portion, 20, 20A . . . insulating resin layer, 21 . . . film adhesive, 30, 35 . . . joined body, 40 . . . semiconductor chip, 45 . . . wiring board (substrate), 46 . . . connection terminal, 50, 50A, 50B . . . semiconductor device, 60 . . . semiconductor wafer (substrate), 80 . . . semiconductor wafer.

1. A method for manufacturing a semiconductor device, the method comprising:
preparing a joined body including a semiconductor substrate, a connection portion provided on a main surface of the semiconductor substrate, and an insulating resin layer provided on the main surface of the semiconductor substrate so as to cover the connection portion; and
grinding the insulating resin layer of the joined body,
wherein, in the grinding, the insulating resin layer is ground such that a surface of the connection portion is exposed.

2. The method for manufacturing a semiconductor device according to claim 1,
wherein, in the grinding, a part of the connection portion is ground together with the insulating resin layer.

3. The method for manufacturing a semiconductor device according to claim 1,
wherein the connection portion includes a connection terminal provided on the main surface of the semiconductor substrate, and a bump provided on the connection terminal, and
wherein, in the grinding, a part of the bump is ground such that a surface of the bump is exposed from the insulating resin layer.

4. The method for manufacturing a semiconductor device according to claim 1,
wherein the preparing the joined body includes:
preparing a semiconductor member including the semiconductor substrate and the connection portion; and
forming the insulating resin layer by providing a liquid insulating resin material on the main surface of the semiconductor substrate so as to cover the connection portion of the semiconductor member, and
wherein the insulating resin layer, when provided on the semiconductor substrate, is thicker than a height of the connection portion.

5. The method for manufacturing a semiconductor device according to claim 1,
wherein the preparing the joined body includes:
preparing a semiconductor member including the semiconductor substrate and the connection portion; and
forming the insulating resin layer by attaching a film-like insulating resin material to the main surface of the semiconductor substrate so as to cover the connection portion of the semiconductor member, and
wherein the insulating resin layer, when attached to the semiconductor substrate, is thicker than a height of the connection portion.

6. The method for manufacturing a semiconductor device according to claim 4,
wherein the preparing the joined body further includes:
performing a curing process on the insulating resin layer of the joined body before the grinding.

7. The method for manufacturing a semiconductor device according to claim 1,
wherein, in the grinding, the insulating resin layer is ground using at least one of a grinder, a surface planer, and a CMP equipment.

8. The method for manufacturing a semiconductor device according to claim 1,
wherein the insulating resin layer comprises an epoxy resin, a curing agent, and an inorganic filler.

9. The method for manufacturing a semiconductor device according to claim 1,
wherein the insulating resin layer comprises an epoxy resin, a curing agent, and a fluxing agent.

10. The method for manufacturing a semiconductor device according to claim 1, further comprising:
singulating the joined body into a plurality of semiconductor chips after grinding the insulating resin layer; and
mounting at least one semiconductor chip of the plurality of semiconductor chips on a substrate.

11. The method for manufacturing a semiconductor device according to claim 10,
wherein the substrate is provided with a terminal to be connected to the connection portion of the joined body, and
wherein the terminal is subjected to a surface treatment that connects to the solder of the connection portion.

12. The method for manufacturing a semiconductor device according to claim 10,
wherein the substrate is a semiconductor wafer having another connection portion, and
wherein, in the mounting, the connection portion of the at least one semiconductor chip is connected to the another connection portion of the semiconductor wafer.

13. The method for manufacturing a semiconductor device according to claim 1, further comprising:
bonding a first semiconductor wafer, which is the joined body after grinding the insulating resin layer, to a second semiconductor wafer having another connection portion,
wherein, in the bonding, the connection portion of the first semiconductor wafer is connected to the another connection portion of the second semiconductor wafer.

14. An insulating resin material for use in forming the insulating resin layer in a method for manufacturing a semiconductor device, the method comprising:
preparing a joined body including a semiconductor substrate, a connection portion provided on a main surface of the semiconductor substrate, and an insulating resin layer provided on the main surface of the semiconductor substrate so as to cover the connection portion; and
grinding the insulating resin layer of the joined body such that a surface of the connection portion is exposed.
